(19) United States
(12) Patent Application Publication
(10) Pub. No.: US 2024/0022180 A1
(43) Pub. Date: Jan. 18, 2024

(54) POWER MODULE FOR A CURRENT CONVERTER FOR AN ELECTRIC AXLE DRIVE OF A MOTOR VEHICLE

(71) Applicant: ZF Friedrichshafen AG, Friedrichshafen (DE)

(72) Inventors: Ake Ewald, Bayreuth (DE); Stefan Hain, Speichersdorf (DE); Fabian Hohmann, Hofbieber (DE); Chandra Gupta Hazarika, Duliajan (IN)

(73) Assignee: ZF Friedrichshafen AG, Friedrichshafen (DE)

(21) Appl. No.: 18/354,090

(22) Filed: Jul. 18, 2023

(30) Foreign Application Priority Data
Jul. 18, 2022 (DE) 102022207271.5

(51) Int. Cl. H02M 7/00; H05K 1/18; H02M 7/537; H02P 27/06

(52) U.S. Cl. CPC H02M 7/003; H05K 1/181; H02M 7/537; H02P 27/06

(57) ABSTRACT

A power module for a current converter for an electric drive of a motor vehicle comprises a termination substrate having electrical contact portions that are electrically isolated from one another, a plurality of power semiconductor elements arranged on the termination substrate, each having a first terminal, a second terminal, and a control terminal, the first terminals of all the power semiconductor elements being electrically connected to a first contact portion of the termination substrate. The power module also includes a first electrical termination, which is electrically connected to the first contact portion of the termination substrate, and a second electrical termination, which is electrically connected to the second terminals of all the power semiconductor elements, the second termination being arranged centrally between and/or above the power semiconductor elements, and an electrical control termination, which is electrically connected to the control terminals of all the power semiconductor elements.

### CROSS-REFERENCE TO RELATED APPLICATION

This application claims priority to German Application No. DE 10 2022 207 271.5, filed on Jul. 18, 2022, the entirety of which is hereby fully incorporated by reference herein.

### FIELD

The present invention relates to a power module for a current converter for an electric axle drive of a motor vehicle, to a current converter for an electric axle drive of a motor vehicle, to an electric axle drive for a motor vehicle, to a motor vehicle, and to a method for operating such a power module.

### BACKGROUND AND SUMMARY

In the field of current converters for electric axle drives for motor vehicles or, in other words, in the field of traction inverters for automotive applications, integrated B6 bridge modules, integrated half-bridge modules or discrete individual switches may conventionally be used. In this context, US2021313243A1 discloses a module that has a leadframe, i.e. a termination frame. The positioning of semiconductor elements in this case is to a large extent driven by the manufacturability of the leadframe, which in the initial design is represented as metal plate. In this case, for example, the outgoing currents can be divided between two connections, which can result in an uneven distribution of currents, causing different loads on the semiconductors.

Against this background, the present invention provides an improved power module for a current converter for an electric axle drive of a motor vehicle, an improved current converter for an electric axle drive of a motor vehicle, an improved electric axle drive for a motor vehicle, an improved motor vehicle and an improved method for operating a power module according to the main claims. Advantageous designs are given by the dependent claims and the following description.

The advantages that can be achieved with the approach presented consist in particular in that it is advantageously possible for contacting of a power module for a current converter for an electric axle drive of a motor vehicle to be realized within a module. In contrast to a module based on a conventional leadframe design, embodiments of the power module make it possible, for example, to achieve uniform conduction of current between semiconductor elements, or more precisely power semiconductor elements, in the region of the so-called power source or, in other words, of a terminal or power terminal of the semiconductor elements. Thus, in particular, a uniform distribution of electric currents, and consequently uniform loading of the semiconductors, can be achieved. According to embodiments it is possible, for example, to realize a power module that can have a centralized source tap or, in other words, a power terminal arranged centrally or in the middle with respect to a plurality of power semiconductor elements. Thus, in particular due to the centralized power-source interfacing, a uniform distribution between the power semiconductor elements becomes possible. In particular, with the power module it is additionally possible to provide connection of all control terminals of the power semiconductor elements to a corresponding terminal pin of the power module.

A power module for a current converter for an electric axle drive of a motor vehicle is presented, the power module having the following features:
a termination substrate having electrical contact portions that are electrically isolated from one another;
a plurality of power semiconductor elements arranged on the termination substrate, each power semiconductor element having a first terminal, a second terminal and a control terminal for controlling a flow of current between the first terminal and the second terminal, the first terminals of all power semiconductor elements being electrically connected to a first contact portion of the termination substrate; and
a first electrical termination for terminating the power module to a first electrical potential, the first termination being electrically connected to the first contact portion of the termination substrate;
a second electrical termination for terminating the power module to a second electrical potential, the second termination being electrically connected to the second terminals of all power semiconductor elements, the second termination being arranged centrally between and/or above the power semiconductor elements; and
an electrical control termination for terminating the power module to an electrical control potential, the control termination being electrically connected to the control terminals of all power semiconductor elements.

The motor vehicle may be, for example, a land vehicle, in particular a passenger car, a motor cycle, a commercial vehicle or the like. The current converter may be in the form of and designated as an inverter. The current converter may be designed to convert the direct electric current from the electric energy store of the motor vehicle into the alternating current for the electric machine of the electric axle drive of the motor vehicle. The power semiconductor elements may be arranged on the first contact portion of the termination substrate. Each of the terminations may comprise a bus bar or a terminal pin. The second termination may be arranged centrally, or in a centered manner, relative to the power semiconductor elements. The second termination in this case may extend along an axis of symmetry between two power semiconductor elements or two groups of power semiconductor elements. Additionally or alternatively, the second termination may at least partially cover, and additionally or alternatively overlap, base regions of bases of the power semiconductor elements. Optionally, the power module may additionally have an electrical signal termination for terminating the power module to an electrical signal potential, in which case the signal termination be electrically connected to optionally additionally provided signal terminals of all power semiconductor elements. The first termination, the second termination, the control termination and the optionally additionally provided signal termination may each be electrically connected directly, or indirectly via intermediate elements, to the respective terminals of the power semiconductor elements. A configuration or division of a surface of the termination substrate in respect of the contact portions may be variable. In this way, advantageously, both electrical power and signals can be conducted. The termination substrate may be in the form of a so-called direct bonded copper substrate, or DBC substrate for short. On the termination substrate, in particular the DBC substrate, all power semiconductor elements may be arranged at a thermally optimal distance from each other. Furthermore, the termination substrate, in particular the DBC substrate, may be designed to enable heat to be dissipated away from the power semiconductor elements. Thus, optimal discharge of heat can be provided by the termination substrate. The power module may further comprise an encapsulation compound. The encapsulation compound may be designed to protect the power semiconductor elements from external influences, to provide electrical insulation and to direct forces for a process, for example a sintering process, for the production of electrical and thermal connections.

For example, each power semiconductor element may have a field-effect transistor or a metal-oxide semiconductor field-effect transistor. For each power semiconductor element in this case, the first terminal may be a drain terminal, the second terminal may be a source terminal, and the control terminal may be a gate terminal. An optionally additionally provided signal terminal may be a kelvin-source terminal. Such an embodiment offers the advantage that even high levels of electrical power, or high electrical currents, can be efficiently conducted and switched.

The power module may also have up to four power semiconductor elements. Each power semiconductor element in this case may have a base area of up to 30 square millimeters. Each power semiconductor element may be in the form of a power electronics chip. Such an embodiment offers the advantage that it becomes possible for up to four power electronics chips, for example each of up to 30 square millimeters in size, to be used in the power module.

According to one embodiment, the second electrical termination may be directly connected to the second terminals of all power semiconductor elements via a material bond. The material bond may be produced by soldering or sintering. Such an embodiment offers the advantage that a large current-carrying area can be provided, and the electrical connection can be realized in a reliable manner by a material bond without further components.

The second electrical termination in this case may have at least one terminal finger per power semiconductor element, or at least one termination region per power semiconductor element. The material bond in this case may be formed between the terminal fingers and the second terminals of the power semiconductor elements, or between the termination regions and the second terminals of the power semiconductor elements. The second electrical termination may be deep-drawn, and additionally or alternatively bent over, in the region of the termination regions. A bend angle in this case may be 180 degrees. Such an embodiment offers the advantage that different shaping of the second termination makes it possible to achieve different positions, and additionally or alternatively, different arrangement patterns of the power semiconductor elements on the termination substrate.

According to one embodiment, the second electrical termination may be connected to the second terminals of all power semiconductor elements via electrical lines. The electrical lines may be in the form of bonding wires. The second termination in this case may be arranged centrally between the power semiconductor elements. Such an embodiment offers the advantage of enabling the power semiconductor elements to be positioned in a flexible manner on the termination substrate, while a uniform distribution of electrical currents from the second termination to the power semiconductor elements can still be achieved.

Also, the control terminals of all power semiconductor elements may be directly connected to the control termination via electrical lines. In this case, optionally additionally provided signal terminals of all power semiconductor elements may be electrically connected to an optionally additionally provided signal termination via electrical lines and a second contact portion of the termination substrate. The electrical lines may be in the form of bonding wires. Such an embodiment offers the advantage that the control terminals of the power semiconductor elements can be electrically terminated in a simple manner that is also flexible in respect of layout.

Alternatively, the control terminals of all power semiconductor elements may be electrically connected to the control termination via electrical lines and a second contact portion of the termination substrate. In this case, optionally additionally provided signal terminals of all power semiconductor elements may be directly connected via electrical lines to an optionally additionally provided signal termination. The electrical lines may be in the form of bonding wires. Such an embodiment offers the advantage that the control terminals of the power semiconductor elements can be electrically terminated in a simple manner that is also flexible in respect of layout.

According to one embodiment, the second electrical termination may be electrically connected to a second contact portion of the termination substrate. In this case, the second contact portion may be connected to the second terminals of all power semiconductor elements via electrical lines. The electrical lines may be in the form of bonding wires. The second contact portion of the termination substrate in this case may be arranged centrally between the power semiconductor elements. Such an embodiment offers the advantage that the electrical load path, with regard to the first and the second electrical termination, the contact portions of the termination substrate and the first and the second terminals of the power semiconductor elements, can be routed in a favorable manner.

The first contact portion of the termination substrate in this case may have a U-shaped outline. The second contact portion of the termination substrate may have a T-shaped outline. In this case, the outlines may be arranged in an interlocking manner. Such an embodiment offers the advantage that a space-saving division of the termination substrate into contact portions and an even distribution of electrical currents to the power semiconductor elements can be achieved.

Further, the control terminals of all power semiconductor elements may be directly connected to the control termination via electrical lines. Moreover, optionally additionally provided signal terminals of all power semiconductor elements may be directly connected via electrical lines to an optionally additionally provided signal termination. The electrical lines may be in the form of bonding wires. Such an embodiment offers the advantage that it becomes possible for the electrical load path to be largely decoupled from the electrical control path, with regard to the control terminals and the control termination, and optionally additionally the signal terminals and the signal termination.

Also presented is a current converter for an electric axle drive of a motor vehicle, the current converter having the following features:
DC terminals for a DC electric current from an electric energy store of the motor vehicle;
a DC link capacitor electrically connected to the DC terminals;
AC terminals for providing an AC electric current for an electric machine of the electric axle drive; and
a plurality of power modules referred to herein, the power modules being designed to convert the direct current into the alternating current.

Furthermore, the invention relates to an electric axle drive for a motor vehicle, comprising at least one electric machine, a transmission means and an embodiment of a current converter described herein.

The current converter may be in the form of an inverter. By use of the current converter, an electric alternating current required for operating the electric machine can be provided. By use of the transmission means, a torque provided by the electric machine may be converted into a driving torque for driving at least one wheel of the motor vehicle. The transmission means may comprise a transmission for reducing the rotational speed of the electric machine and, optionally, a differential.

The invention additionally relates to a motor vehicle having an embodiment of a current converter mentioned herein, and additionally or alternatively having an embodiment of an electric axle drive mentioned herein.

Accordingly, a motor vehicle may comprise a current converter mentioned herein and, additionally or alternatively, an electric axle drive mentioned herein.

Also presented is a method for operating an embodiment of a power module mentioned herein, the method comprising the following steps:
applying the first electrical potential, via the first electrical termination and the first contact portion of the termination substrate, to the first terminals of all power semiconductor elements, and the second electrical potential, via the second electrical termination, to the second terminals of all power semiconductor elements; and
applying the electrical control potential, via the electrical control termination, to the control terminals of all power semiconductor elements, in order to control the flow of current between the first terminal and the second terminal of each power semiconductor element.

Execution of such a method allows at least one power module mentioned herein can be operated in an advantageous manner, in particular in combination with an embodiment of a current converter mentioned herein.

The invention is explained in greater detail by way of example with reference to the accompanying drawings.

### BRIEF DESCRIPTION OF THE DRAWINGS

FIG. 1 shows a schematic representation of an exemplary embodiment of a motor vehicle;

FIG. 2 shows a schematic representation of an exemplary embodiment of a current converter for an electric axle drive of a motor vehicle;

FIG. 3 shows a schematic representation of an exemplary embodiment of a power module for a current converter for an electric axle rive of a motor vehicle;

FIG. 4 shows a schematic representation of an exemplary embodiment of a power module for a current converter for an electric axle drive of a motor vehicle;

FIG. 5 shows a detail view of the power module from FIG. 4;

FIG. 6 shows a schematic representation of an exemplary embodiment of a power module for a current converter for an electric axle drive of a motor vehicle;

FIG. 7 shows a schematic representation of an exemplary embodiment of a power module for a current converter for an electric axle drive of a motor vehicle;

FIG. 8 shows a schematic representation of an exemplary embodiment of a power module for a current converter for an electric axle drive of a motor vehicle; and

FIG. 9 shows a flow diagram of an exemplary embodiment of a method for operating a power module.

### DETAILED DESCRIPTION

In the following description of preferred embodiments of the present invention, the same or similar reference designations are used for the elements, represented in the various figures, that are similar in their function, but description of these elements is not repeated.

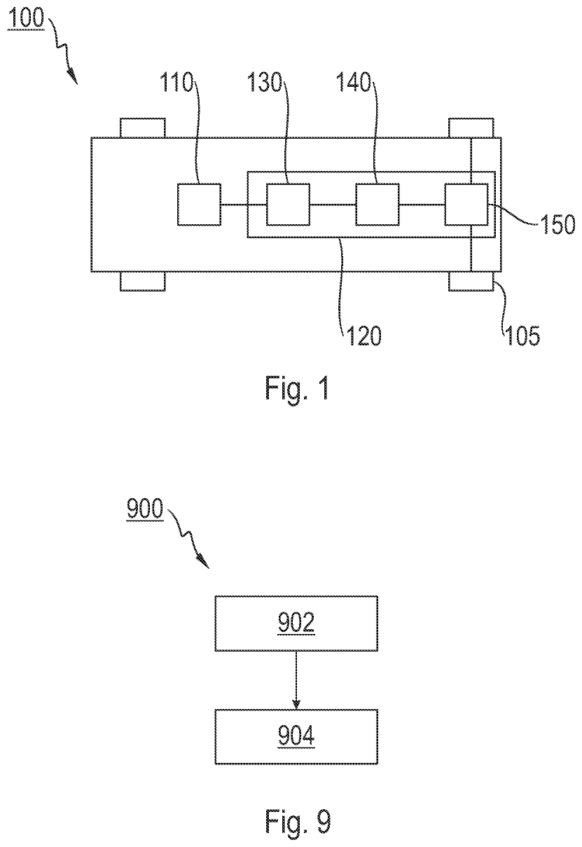

FIG. 1 shows a schematic representation of an exemplary embodiment of a motor vehicle 100. Of the motor vehicle 100, in this case wheels 105, by way of example only four wheels 105, an electric energy store 110, for example a battery, and an electric axle drive 120 are shown in the representation of FIG. 1. The electric axle drive 120 comprises a current converter 130, an electric machine 140 and a transmission means 150.

Electrical energy for operating the electric machine 105 is provided by an energy supply means, in this case the electric energy store 110. The electric energy store 110 is designed to provide direct current, which is converted to alternating current, for example three-phase alternating current, by use of a current converter 130 of the electric axle drive 120, and provided to the electric machine 140. A shaft driven by the electric machine 140 is coupled to at least one wheel 105 of the motor vehicle 100, either directly or via the transmission means 150. Thus, the motor vehicle 100 can be moved by means of the electric machine 140. According to an exemplary embodiment, the electric axle drive 120 comprises a housing in which the current converter 130, the electric machine 140 and the transmission means 150 are arranged.

The current converter 130 and its components, in particular, are discussed in greater detail with reference to the following figures.

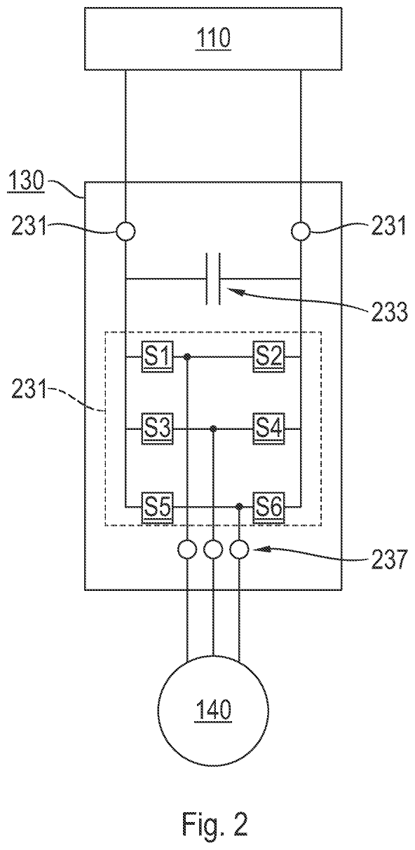

FIG. 2 shows a schematic representation of an embodiment of a power converter 130 for an electric axle drive of a motor vehicle. The power converter 130 in this case corresponds or is similar to the power converter in FIG. 1. Furthermore, in addition to the power converter 130, the electrical energy store 110 and the electrical machine 140 of the electrical axle drive are also shown for illustration in FIG. 2. The power converter 130 comprises DC terminals 231, a DC link capacitor 233, a plurality of power modules 235, and AC terminals 237.

The DC terminals 231 are provided for a DC electrical current from the electrical energy store 110 of the motor vehicle. In other words, the current converter 130 is terminated, or can be terminated, to the electrical energy store 110 via the DC terminals 231. The DC link capacitor 233 is electrically connected to the first of the DC terminals 231 and the second of the DC terminals 231. The AC terminals 237 are for providing an AC electrical current for the electric machine 140 of the electric axle drive. In other words, the current converter 130 is terminated, or can be terminated, to the electric machine 140 via the AC terminals 237. The DC terminals 231 and/or the AC terminals 237 are each formed, for example, to receive one end of a power cable and to contact it mechanically and electrically, for example by screw connection, clamping or soldering.

The power modules 235 comprise switching means and are designed to convert the direct current into alternating current. The power modules 235 are also discussed in greater detail with reference to the following figures. According to the exemplary embodiment represented here, the current converter 130 comprises, as an example, only six power modules 235, in this case a first power module S1, a second power module S2, a third power module S3, a fourth power module S4, a fifth power module S5 and a sixth power module S6. The power modules 235, or S1, S2, S3, S4, S5 and S6, are interconnected in a B6 bridge circuit. Thus, a first of the DC terminals 231 is electrically connected to a first terminal of the first power module S1, to a first terminal of the third power module S3 and to a first terminal of the fifth power module S5. A second of the DC terminals 231 is electrically connected to a first terminal of the second power module S2, to a first terminal of the fourth power module S4, and to a first terminal of the sixth power module S6. A first of the AC terminals 237 is electrically connected to a second terminal of the first power module S1 and to a second terminal of the second power module S2. A second of the AC terminals 237 is electrically connected to a second terminal of the third power module S3 and to a second terminal of the fourth power module S4. A third of the AC terminals 237 is electrically connected to a second terminal of the fifth power module S5 and to a second terminal of the sixth power module S6.

According to an exemplary embodiment, the current converter 130 may be operated in the reverse direction, such that the electric machine 140 can be used as a generator to charge the electric energy store 110.

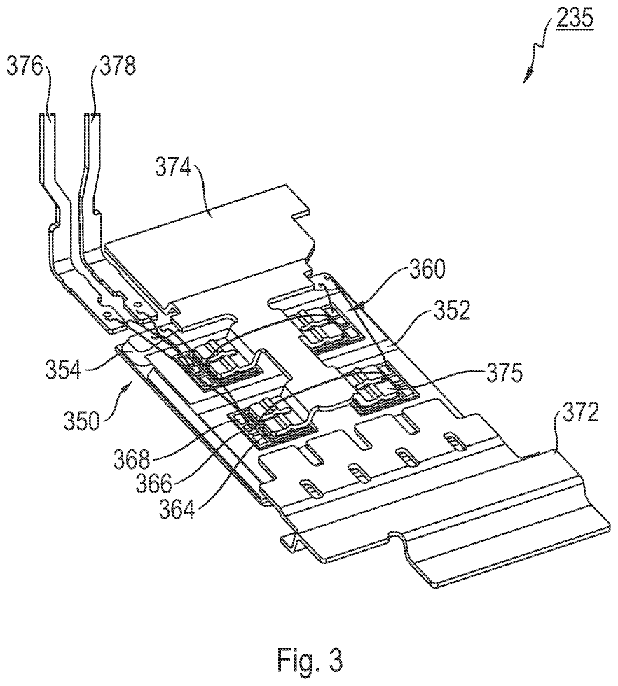

FIG. 3 shows a schematic representation of an exemplary embodiment of a power module 235 for a current converter for an electric axle drive of a motor vehicle. The power module 235 in this case corresponds or is similar to one of the power modules in FIG. 2. The power module 235 comprises a termination substrate 350, a plurality of power semiconductor elements 360 and electrical termination 372, 374, 376 and 378, in this case for example a first electrical termination 372, a second electrical termination 374, an electrical control termination 376 and, optionally, additionally an electrical signal termination 378.

The termination substrate 350 comprises electrical contact portions 352, 354 that are electrically isolated from one another, in this case for example a first contact portion 352 and a second contact portion 354. According to the exemplary embodiment represented here, the termination substrate 350 is in the form of a so-called direct bonded copper substrate, in short DBC substrate. The power semiconductor elements 360 are arranged on the termination substrate 350. According to the exemplary embodiment represented here, the power module 235 comprises, as an example, four power semiconductor elements 360. In particular, each power semiconductor element 360 in this case has a base area of up to 30 square millimeters.

Each power semiconductor element 360 comprises a first terminal, concealed in this representation by the power semiconductor element 360 itself, a second terminal 364, a control terminal 366 for controlling a flow of current between the first terminal and the second terminal 364 and, optionally, additionally a signal terminal 368. According to the exemplary embodiment represented herein, each power semiconductor element 360 comprises, or is in the form of, a field-effect transistor or a metal-oxide semiconductor field-effect transistor. Thus, for each power semiconductor element 360, the first terminal is a drain terminal, the second terminal 364 is a source terminal, the control terminal 366 is a gate terminal, and the signal terminal 368 is a so-called kelvin-source terminal.

The first terminals of all power semiconductor elements 360 are electrically connected to the first contact portion 352 of the termination substrate 350. The first contact portion 352 of the termination substrate 350 is electrically connected to the first termination 372. The first termination 372 serves to terminate the power module 235 to a first electrical potential, in particular an electrical drain potential. The first termination 372 is realized, for example, as a bus bar and is electrically connected to the first contact portion 352 in a symmetrical manner.

The second terminals 364 of all power semiconductor elements 360 are electrically connected to the second electrical termination 374. The second termination 374 serves to terminate the power module 235 to a second electrical potential, in particular an electrical source potential. The second termination 374 is arranged centrally between the power semiconductor elements 360. In this case, the second termination 374 extends, for example, along an axis of symmetry between two groups of the power semiconductor elements 360. In this case, according to the exemplary embodiment represented here, the second terminals 364 of the power semiconductor elements 360 are arranged facing toward the axis of symmetry, with the control terminals 366 and the signal terminals 368 of the power semiconductor elements 360 being arranged facing away from the symmetry. According to the exemplary embodiment represented here, the second termination 374 is directly connected to the second terminals 364 of all power semiconductor elements 360 via a material bond. The second termination 374 in this case comprises at least one terminal finger 375, in this case two terminal fingers 375, per power semiconductor element 360. The material bond is formed between the respective terminal fingers 375 and the respective second terminals 364 of the power semiconductor elements 360.

The control terminals 366 of all power semiconductor elements 360 are electrically connected to the control termination 376. The control termination 376 serves to terminate the power module 235 to an electrical control potential, in particular an electrical gate potential. According to the exemplary embodiment represented here, the control terminals 366 of all power semiconductor elements 360 are directly connected to the control termination 376 via electrical lines.

The signal terminals 368 of all power semiconductor elements 360 are electrically connected to the signal termination 378. The signal termination 378 serves to terminate the power module 235 to an electrical signal potential, in particular an electrical kelvin-source potential. According to the exemplary embodiment represented here, the signal terminals 368 of all power semiconductor elements 360 are electrically connected to the signal termination 378 via electrical lines and the second contact portion 354 of the termination substrate 350.

The first electrical termination 372 is led to the termination substrate 350 from a first side. The second electrical termination 374 and, optionally, additionally the control termination 376 and the signal termination 378 are led to the termination substrate 350 from a second side that faces away from the first side.

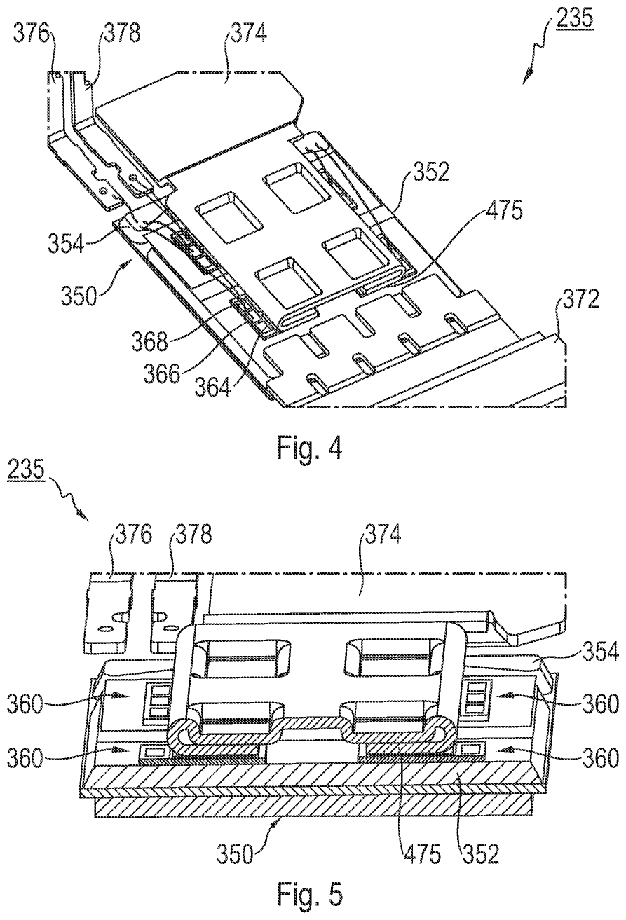

FIGS. 4 to 6 described below show further exemplary embodiments of the power module 235, in which in particular a central power-source interfacing, or second electrical termination 374, is provided in each case in order to achieve a uniform distribution of current between the power semiconductor elements 360.

FIG. 4 shows a schematic representation of an exemplary embodiment of a power module 235 for a current converter for an electric axle drive of a motor vehicle. The power module 235 in this case corresponds to the power module in FIG. 3, with the exception that the second electrical termination 374 is of a different design, and the control terminals 366 and the signal terminals 368 of the power semiconductor elements 360 are electrically connected in a different manner to the respective termination 376, 378. In other words, FIG. 4 shows another exemplary embodiment of the power module 235 with a focus on a wide current-carrying path.

According to the exemplary embodiment represented here, the second electrical termination 374 comprises one termination region 475 per power semiconductor element 360. The material bond is formed between the termination regions 475 of the second termination 374 and the second terminals 364 of the power semiconductor elements 360. The second electrical termination 374 is bent over and deep-drawn or press-formed in the region of the termination regions 475. More specifically, the termination regions 475 of the second termination 374 are bent over 180 degrees relative to a plane of main extent of the second termination 374, and a plate portion of the second termination 374 extending along the plane of main extent is deep-drawn or press-formed in the region of the termination regions 475. This is discussed in greater detail with reference to FIG. 5.

According to the exemplary embodiment represented here, the control terminals 366 of all power semiconductor elements 360 are electrically connected to the control termination 376 via electrical lines and the second contact portion 354 of the termination substrate 350. The signal terminals 368 of all power semiconductor elements 360 are directly connected to the signal termination 378 via electrical lines.

FIG. 5 shows a detail view of the power module 235 of FIG. 4, in a partially sectional view, as an example. In other words, FIG. 5 shows a detail view of the bent-over, folded-over or folded-down region of the second termination 374 from FIG. 4 with the termination regions 475. In this case, the power module 235 is represented in section, along a section plane that extends transversely through the second termination 374 and through two of the power semiconductor elements 360. In particular, for reasons of clarity, in the representation of FIG. 5 the terminals of the power semiconductor elements 360 are indicated on the power module 235, and also the electrical lines have been omitted from the representation.

With reference to FIG. 4 and FIG. 5, it can be seen that the second electrical termination 374 has a press-formed portion of the metal plate represented at the top of the figures, in order to compensate for the necessary radius of bend of the fold-over of the tab for the termination regions 475, such that a process contact force for the material bond, for example sintering/soldering, can be realized between the second terminals of the power semiconductor elements and the second termination 374, which may also be referred to as a source clip. Thus, the termination region 475 contacts the impressed regions. Alternatively, a plastic or metal spacer or transition component may be provided to bridge the distance.

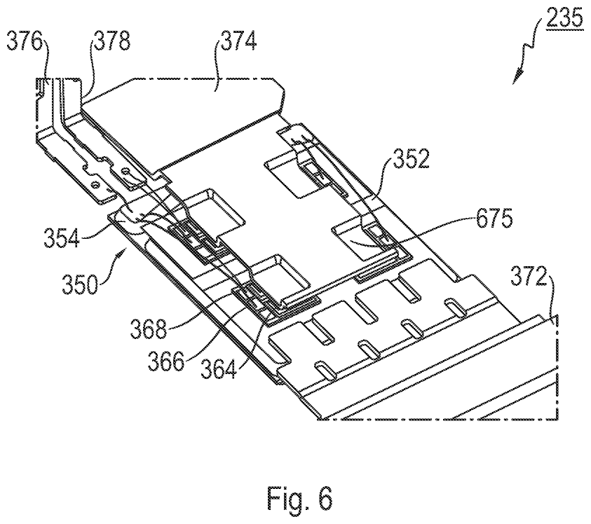

FIG. 6 shows a schematic representation of an exemplary embodiment of a power module 235 for a current converter for an electric axle drive of a motor vehicle. The power module 235 in this case corresponds to the power module in FIG. 3 with the exception that the second electrical termination 374 is of a different design, and the control terminals 366 and the signal terminals 368 of the power semiconductor elements 360 are electrically connected to the respective termination 376, 378 as in FIG. 4. Also, the power module 235 corresponds to the power module in FIG. 4 with the exception that the second electrical termination 374 is of a different design.

According to the exemplary embodiment represented here, the second electrical termination 374 comprises one termination region 675 per power semiconductor element 360. The material bond is formed between the termination regions 675 of the second termination 374 and the second terminals 364 of the power semiconductor elements 360. The second electrical termination 374 is deep-drawn or press-formed in the region of the termination regions 675. More specifically, the termination regions 675 are themselves deep-drawn or impressed.

According to the exemplary embodiment represented here, the control terminals 366 of all power semiconductor elements 360 are electrically connected to the control termination 376 via electrical lines and the second contact portion 354 of the termination substrate 350. The signal terminals 368 of all power semiconductor elements 360 are directly connected to the signal termination 378 via electrical lines.

In other words, FIG. 6 shows an exemplary embodiment of a power module 235 with impressed semiconductor terminals, or termination regions 675, of the second electrical termination 374. In this case, the impressed region, i.e. the termination regions 675, of the second electrical termination 374 is or is to be directly materially bonded to the power semiconductor elements 360. In particular, this allows good kelvin-source interfacing with given semiconductor positioning on the termination substrate 350.

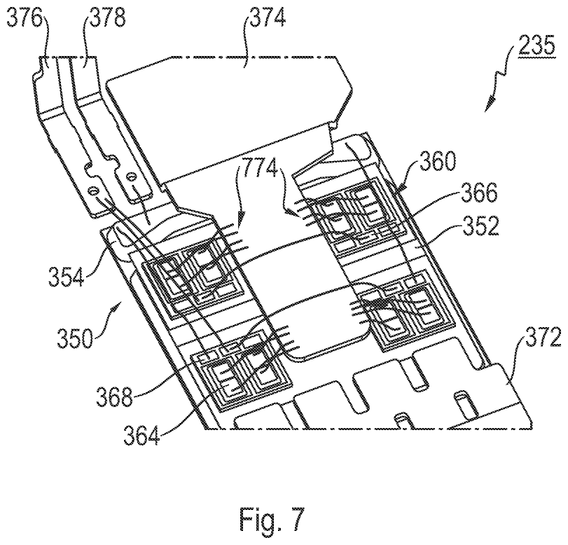

FIG. 7 shows a schematic representation of an exemplary embodiment of a power module 235 for a current converter for an electric axle drive of a motor vehicle. The power module 235 in this case corresponds to the power module in FIG. 3, with the exception that the second electrical termination 374 is of a different design and the power semiconductor elements 360 are arranged with a different orientation on the termination substrate 350.

According to the exemplary embodiment represented here, the second electrical termination 374 is connected to the second terminals 364 of all power semiconductor elements 360 via electrical lines 775. The electrical lines 775 are, for example, bonding wires. Each power semiconductor element 360 comprises, for example, four second terminals 364. Thus, each of the power semiconductor elements 360 is electrically connected to the second electrical termination 374 via four electrical lines 775. Furthermore, the second termination 374 extends, for example, transversely or perpendicularly with respect to an axis of symmetry between two groups of the power semiconductor elements 360. In this case, according to the exemplary embodiment represented here, the second terminals 364 of the power semiconductor elements 360 are arranged facing away from the axis of symmetry, with the control terminals 366 and the signal terminals 368 of the power semiconductor elements 360 being arranged facing toward the symmetry.

In other words, FIG. 7 shows an exemplary embodiment of a power module 235 having a connection via electrical lines 775 or, bonding wires, to the second electrical termination 374, or power-source terminal. In this case, furthermore, the gate pin, or control termination 376, is connected to all gates, or control terminals 366, of the four power semiconductor elements 360. The power semiconductor elements 360 on the pin side have two bonding contacts. This enables the kelvin-source terminal, or signal terminal 368, to be contacted via the island, or the second termination region 354, located on the source side, or second termination 374 side, on the termination substrate 350.

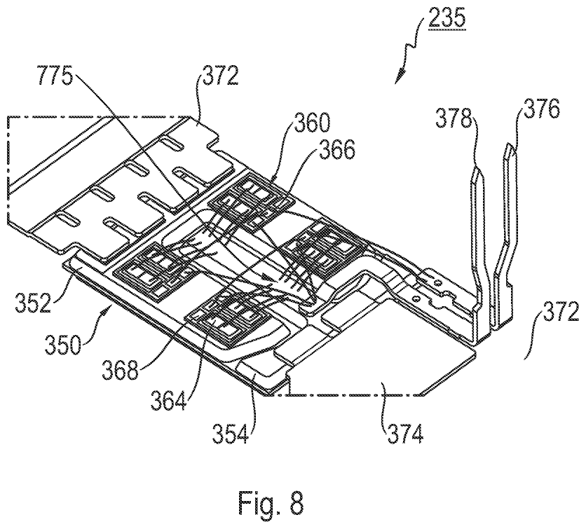

FIG. 8 shows a schematic representation of an exemplary embodiment of a power module 235 for a current converter for an electric axle drive of a motor vehicle. The power module 235 in this case corresponds to the power module in FIG. 7, with the exception that the second electrical termination 374 is of a different design.

According to the exemplary embodiment represented here, the second electrical termination 374 is electrically connected to the second contact portion 354 of the termination substrate 350. In this case, the second contact portion 354 is connected to the second terminals 364 of all power semiconductor elements 360 via electrical lines 775. For example, in this case the first contact portion 352 of the termination substrate 350 has a U-shaped outline, and the second contact portion 354 of the termination substrate 350 has a T-shaped outline. The outlines are arranged in an interlocking manner. Furthermore, in this case the control terminals 366 of all power semiconductor elements 360 are directly connected to the control termination 376 via electrical lines. In addition, the signal terminals 368 of all power semiconductor elements 360 are directly connected to the signal termination 378 via electrical lines.

In other words, FIG. 8 shows an exemplary embodiment of a power module 235 having a centralized source terminal in the termination substrate 350, or DBC substrate. In this case, a two-layer source connection is provided, with the power-source pin, or second termination 374, contacted on the termination substrate 350, and the kelvin-source pin, or signal termination 378, arranged above. This provides an independent kelvin-source terminal, and thus enables the control path to be largely decoupled from the load path.

FIG. 9 shows a flow diagram of an exemplary embodiment of a method 900 for operating a power module. The power module operated by the method for operating 900 is the same as or similar to the power module of one of the figures described above. The method 900 for operating can thus be executed in conjunction with the power module from one of the figures described above or a similar power module. The power module in this case is optionally part of the current converter of one of the figures described above or a similar current converter. The method 900 for operating comprises a first step 902 of applying, and a second step 904 of applying.

In the first step 902 of applying, the first electrical potential is applied to the first terminals of all power semiconductor elements via the first electrical termination and the first contact portion of the termination substrate, and the second electrical potential is applied to the second terminals of all power semiconductor elements via the second electrical termination. In the second step 904 of applying, the electrical control potential is applied to the control terminals of all power semiconductor elements via the electrical control termination, in order to control the flow of current between the first terminal and the second terminal of each power semiconductor element.

### REFERENCE DESIGNATIONS

100 motor vehicle
105 wheels
110 electric energy store
120 electric axle drive
130 current converter
140 electric machine
150 transmission means
231 DC terminals
233 DC link capacitor
235 power modules
237 AC terminals
S1 first power module
S2 second power module
S3 third power module
S4 fourth power module
S5 fifth power module
S6 sixth power module
350 termination substrate
352 first contact portion
354 second contact portion
360 power semiconductor element
364 second terminal
366 control terminal
368 signal terminal
372 first electrical termination
374 second electrical termination
375 terminal finger
376 electrical control termination
378 electrical signal termination
475 termination region
675 termination region
775 electrical lines
900 method for operating
902 first step of applying
904 second step of applying

1. A power module for a current converter for an electric axle drive of a motor vehicle, the power module comprising:
a termination substrate having electrical contact portions that are electrically isolated from one another;
a plurality of power semiconductor elements arranged on the termination substrate, each power semiconductor element having a first terminal, a second terminal, and a control terminal for controlling a flow of current between the first terminal and the second terminal, the first terminals of all power semiconductor elements being electrically connected to a first contact portion of the termination substrate;
a first electrical termination for terminating the power module to a first electrical potential, the first termination being electrically connected to the first contact portion of the termination substrate;
a second electrical termination for terminating the power module to a second electrical potential, the second termination being electrically connected to the second terminals of all power semiconductor elements, the second termination being arranged centrally between and/or above the power semiconductor elements; and
an electrical control termination for terminating the power module to an electrical control potential, the control termination being electrically connected to the control terminals of all power semiconductor elements.

2. The power module according to claim 1, wherein each power semiconductor element comprises a field-effect transistor or a metal-oxide semiconductor field-effect transistor, and wherein, for each power semiconductor element the first terminal is a drain terminal, the second terminal is a source terminal, and the control terminal is a gate terminal.

3. The power module according to claim 1, comprising up to four power semiconductor elements, each power semiconductor element having a base area of up to 30 square millimeters.

4. The power module according to claim 1, wherein the second electrical termination is directly connected to the second terminals of all power semiconductor elements via a material bond.

5. The power module according to claim 4, wherein the second electrical termination comprises at least one terminal finger per power semiconductor element, the material bond being formed between the terminal fingers and the second terminals of the power semiconductor elements, the second electrical termination being deep-drawn and/or bent over.

6. The power module according to claim 4, wherein the second electrical termination comprises at least one termination region per power semiconductor element, the material bond being formed between the termination regions and the second terminals of the power semiconductor elements, the second electrical termination being deep-drawn and/or bent over in the region of the termination regions.

7. The power module according to claim 1, wherein the second electrical termination is connected to the second terminals of all the power semiconductor elements via electrical lines.

8. The power module according to claim 1, wherein the control terminals of all the power semiconductor elements are directly connected to the control termination via electrical lines.

9. The power module according to claim 1, wherein the control terminals of all the power semiconductor elements are electrically connected to the control termination via electrical lines and a second contact portion of the termination substrate.

10. The power module according to claim 1, where the second electrical termination is electrically connected to a second contact portion of the termination substrate, the second contact portion being connected to the second terminals of all the power semiconductor elements via electrical lines.

11. The power module according to claim 10, wherein the first contact portion of the termination substrate has a U-shaped outline, and the second contact portion of the termination substrate has a T-shaped outline, the outlines being arranged in an interlocking manner.

12. The power module according to claim 10, wherein the control terminals of all the power semiconductor elements are directly connected to the control termination via electrical lines.

13. A current converter for an electric axle drive of a motor vehicle, the current converter comprising:
DC terminals for a DC electric current from an electric energy store of the motor vehicle;
a DC link capacitor electrically connected to the DC terminals;
AC terminals for providing an AC electric current for an electric machine of the electric axle drive; and
a plurality of power modules according to claim 1, the plurality of power modules configured to convert the DC electric current into the AC electric current.

14. An electric axle drive for a motor vehicle, comprising at least one electric machine, a transmission, and the current converter according to claim 13.

15. A motor vehicle comprising the electric axle drive according to claim 14.

16. A motor vehicle comprising the current converter according to claim 12.

17. A method for operating a power module, the method comprising:
applying a first electrical potential, via a first electrical termination of the power module and a first contact portion of a termination substrate of the module, to first terminals of a plurality of power semiconductor elements arranged on the termination substrate;
applying a second electrical potential, via a second electrical termination of the power module, to second terminals of the plurality of power semiconductor elements; and
applying an electrical control potential, via an electrical control termination, to control terminals of the plurality of power semiconductor elements, in order to control a flow of current between the first terminals and the second terminals of each of the plurality of power semiconductor elements.
